(19) United States
(12) Patent Application Publication
(10) Pub. No.: US 2021/0391313 A1
(43) Pub. Date: Dec. 16, 2021

(54) Electronic device

(71) Applicant: InnoLux Corporation, Miao-Li County (TW)

(72) Inventors: Jui-Jen YUEH, Miao-Li County (TW); Kuan-Feng LEE, Miao-Li County (TW); Yuan-Lin WU, Miao-Li County (TW)

(21) Appl. No.: 17/458,233

(22) Filed: Aug. 26, 2021

Related U.S. Application Data
(63) Continuation of application No. 16/161,882, filed on Oct. 16, 2018.

(51) Int. Cl. H01L 25/16; H01L 25/075; G09G 3/32; H01L 27/12; H01L 33/50

(52) U.S. Cl. CPC H01L 25/167; H01L 25/0753; H01L 27/1218; H01L 27/124; H01L 33/50; G09G 3/32

(57) ABSTRACT

An electronic device is disclosed, which includes: a substrate; a first signal line; switch elements including a first switch element, which is electrically connected to the first signal line; electronic modules including a first electronic module, which includes a first substrate, first electronic elements, first electrodes, a second electrode and a first contact pads, wherein the first electrodes are disposed between the first substrate and the second electrode, the first substrate is disposed between the first electrodes and the first contact pads, and the second electrode is electrically connected to the first electronic elements; and a light alternating layer; wherein at least two of the first electronic elements respectively includes an LED chip, and a light conversion element, and the light alternating layer is continuously disposed on two adjacent light conversion elements of the at least two of the first electronic elements.

### CROSS REFERENCE TO RELATED APPLICATION

This application is a continuation (CA) of U.S. patent application for “ELECTRONIC DEVICE”, U.S. application Ser. No. 16/161,882 filed Oct. 16, 2018, and the subject matter of which is incorporated herein by reference.

### BACKGROUND

### 1. Field

The present disclosure relates to an electronic device. More specifically, the present disclosure relates to a tiled electronic device.

### 2. Description of Related Art

With the continuous advancement of technologies related to display devices, the applications of the display devices are not limited to monitors, mobile phones, laptops, televisions, etc. Nowadays, tiled display systems are developed to extend the applications of the display devices to video walls, advertising boards, and other electronic devices for displaying large images.

Except for the tiled display system, tiled antenna systems or tiled sensing systems are also developed to make, for example, the walls of buildings, have antenna or sensing functions.

However, the number of the elements capable of being driven by one driver IC is limited, thus a great amount of driver ICs are used to make the electronic device exhibiting its function.

Therefore, it is desirable to provide a novel electronic device to lower the number of the used driver ICs.

### SUMMARY

The present disclosure provides an electronic device, which comprises: a substrate; a first signal line disposed on the substrate; a plurality of switch elements disposed on the substrate and comprising a first switch element, wherein the first switch element is electrically connected to the first signal line; a plurality of electronic modules disposed on the substrate and comprising a first electronic module, wherein the first electronic module comprises a first substrate, a plurality of first electronic elements disposed on the first substrate, a plurality of first electrodes, a second electrode and a plurality of first contact pads disposed on the substrate, wherein the plurality of first electrodes are disposed between the first substrate and the second electrode, the first substrate is disposed between the plurality of first electrodes and the plurality of first contact pads, and the second electrode is electrically connected to the plurality of first electronic elements; and a light alternating layer disposed on the substrate; wherein at least two of the plurality of first electronic elements respectively comprise an LED chip, and a light conversion element disposed on the LED chip, and the light alternating layer is continuously disposed on two adjacent light conversion elements of the at least two of the plurality of first electronic elements.

A method for manufacturing an electronic device is also provided, which comprise: providing a substrate; forming a first signal line on the substrate; forming a plurality of switch elements on the substrate, wherein the plurality of switch elements comprises a first switch element; disposing a plurality of electronic modules on the substrate, wherein the plurality of electronic modules comprises a first electronic module, and the first electronic module comprises a first substrate, a plurality of first electronic elements disposed on the first substrate, a plurality of first electrodes, a second electrode and a plurality of first contact pads disposed on the substrate, wherein the plurality of first electrodes are disposed between the first substrate and the second electrode, the first substrate is disposed between the plurality of first electrodes and the plurality of first contact pads, and the second electrode is electrically connected to the plurality of first electronic elements; and disposing a light alternating layer on the substrate; wherein at least two of the plurality of first electronic elements respectively comprise an LED chip, and a light conversion element disposed on the LED chip, and the light alternating layer is continuously disposed on two adjacent light conversion elements of the at least two of the plurality of first electronic elements.

Other novel features of the disclosure will become more apparent from the following detailed description when taken in conjunction with the accompanying drawings.

### BRIEF DESCRIPTION OF THE DRAWINGS

FIG. 1A is a top view of an electronic device according to Embodiment 1 of the present disclosure.

FIG. 1B is a cross-sectional view of an electronic device according to Embodiment 1 of the present disclosure.

FIG. 2 is a schematic view showing a part of an electronic device according to Embodiment 1 of the present disclosure.

FIG. 3 is a circuit diagram of a part of an electronic device according to Embodiment 1 of the present disclosure.

FIG. 4 is a cross-sectional view of an electronic device according to Embodiment 1 of the present disclosure.

FIG. 5 is a cross-sectional view of an electronic device according to Embodiment 2 of the present disclosure.

FIG. 6 is a cross-sectional view of an electronic device according to Embodiment 3 of the present disclosure.

FIG. 7 is a cross-sectional view of an electronic device according to Embodiment 4 of the present disclosure.

FIG. 8 is a cross-sectional view of an electronic device according to Embodiment 5 of the present disclosure.

### DETAILED DESCRIPTION OF EMBODIMENT

The following embodiments when read with the accompanying drawings are made to clearly exhibit the above-mentioned and other technical contents, features and/or effects of the present disclosure. Through the exposition by means of the specific embodiments, people would further understand the technical means and effects the present disclosure adopts to achieve the above-indicated objectives. Moreover, as the contents disclosed herein should be readily understood and can be implemented by a person skilled in the art, all equivalent changes or modifications which do not depart from the concept of the present disclosure should be encompassed by the appended claims.

Furthermore, the ordinals recited in the specification and the claims such as “first”, “second” and so on are intended only to describe the elements claimed and imply or represent neither that the claimed elements have any proceeding ordinals, nor that sequence between one claimed element and another claimed element or between steps of a manufacturing method. The use of these ordinals is merely to differentiate one claimed element having a certain designation from another claimed element having the same designation.

Furthermore, the terms recited in the specification and the claims such as “above”, “over”, or “on” are intended not only directly contact with the other element, but also intended indirectly contact with the other element. Similarly, the terms recited in the specification and the claims such as “beneath”, “below”, or “under” are intended not only directly contact with the other element but also intended indirectly contact with the other element.

Furthermore, the terms recited in the specification and the claims such as “connect” is intended not only directly connect with other element, but also intended indirectly connect and electrically connect with other element.

In addition, the features in different embodiments of the present disclosure can be mixed to form another embodiment.

### Embodiment 1

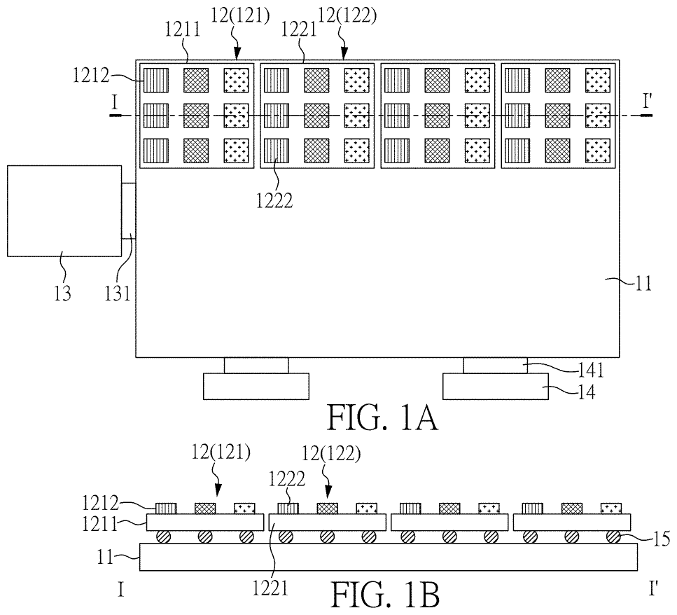

FIG. 1A is a top view of an electronic device of the present embodiment, and FIG. 1B is a cross-sectional view along the line I-I′ indicated in FIG. 1A.

As shown in FIG. 1A and FIG. 1B, the electronic device of the present embodiment comprises: a substrate 11; a plurality of electronic modules 12 (comprising a first electronic module 121 and a second electronic module 122) disposed on the substrate 11; a controller 13 electrically connected to the substrate 11 via a circuit board 131; and a driving element 14 electrically connected to the substrate 11 via a circuit board 141. Herein, the substrate 11 is a driving substrate with circuits formed thereon, and the electronic modules 12 are electrically connected to circuits (such as the first signal line S1) on the substrate 11 through conductive elements 15. The controller 13 can be a timing controller (T-con controller). The driving element 14 can be a driver IC. In some embodiments, the driver IC is a power source for providing a constant voltage or a constant current. However, the present disclosure is not limited thereto.

In the present embodiment, the electronic modules 12 are disposed on the substrate 11 and arranged in juxtaposition to form an electronic device. In other embodiments, multiple electronic devices are coupled together to form a tiled electronic device. In FIG. 1A, not all the electronic modules 12 but only four electronic modules 12 are shown. However, the present disclosure is not limited thereto. The number and the arrangement of the electronic modules 12 can be adjusted according to the need.

In addition, the electronic modules 12 may respectively comprise a substrate and a plurality of electronic elements disposed on the substrate. For example, the first electronic module 121 comprises a first substrate 1211, and a plurality of first electronic elements 1212 disposed on the first substrate 1211. The second electronic module 122 comprises a second substrate 1221, and plurality of second electronic elements 1222 formed on the second substrate 1221. Herein, each of the electronic modules 12 comprises nine electronic elements (for example, the first electronic elements 1212 and the second electronic elements 1222), but the present disclosure is not limited thereto. The number and the arrangement of the electronic elements can be adjusted according to the need.

Herein, the substrate 11 and the substrate of the electronic modules 12 (for example, the first substrate 1211 and the second substrate 1221) may respectively comprise a quartz substrate, a glass substrate, a wafer, a sapphire substrate, or etc. The substrate 11 and the substrate of the electronic modules 12 (for example, the first substrate 1211 and the second substrate 1221) may also respectively comprise a flexible substrate or a film, and the material of which can comprise polycarbonate (PC), polyimide (PI), polypropylene (PP), polyethylene terephthalate (PET), or other plastic or polymer material. When the flexible substrate or a film is used, the electronic device is a flexible electronic device. However, the present disclosure is not limited thereto.

The conductive elements 15 can respectively be a solder bump, a metal pillar, or a conductive particle. The conductive elements may respectively comprise Ag, Al, Ni, Cr, Cu, Au, Pd, Pt, Sn, W, Rh, Jr, Ru, Mg, Zn, or an alloy thereof, but the present disclosure is not limited to. Alternatively, the conductive elements 15 can be formed by using conductive paste such as Ag paste or an anisotropic conductive film (ACF), but the present disclosure is not limited thereto.

The electronic elements of the electronic modules 12 (for example, the first electronic elements 1212 of the first electronic module 121 and the second electronic elements 1222 of the second electronic module 122) can respectively a light emitting diode, an antenna unit, a sensor, or a combination thereof. The type of the antenna unit is not particularly limited, as long as the antenna unit can achieve the function of receiving and transmitting signals. The sensor capable of using in the electronic device of the present embodiment can be a fingerprint sensor, an iris sensor, a retina sensor, a facial sensor, a vein sensor, a voice sensor, a motion sensor, a gesture sensor, or a DNA sensor. The light emitting diode capable of using in the electronic device of the present embodiment can be organic light-emitting diodes (OLED), normal light-emitting diodes (normal LEDs), mini light-emitting diodes (mini-LEDs), micro light-emitting diodes (micro-LEDs), or quantum-dot light-emitting diodes (QLEDs).

In the present embodiment, the electronic elements (for example, the first electronic elements 1212 and the second electronic elements 1222) are light emitting diodes. Thus, the electronic device of the present embodiment is a display device.

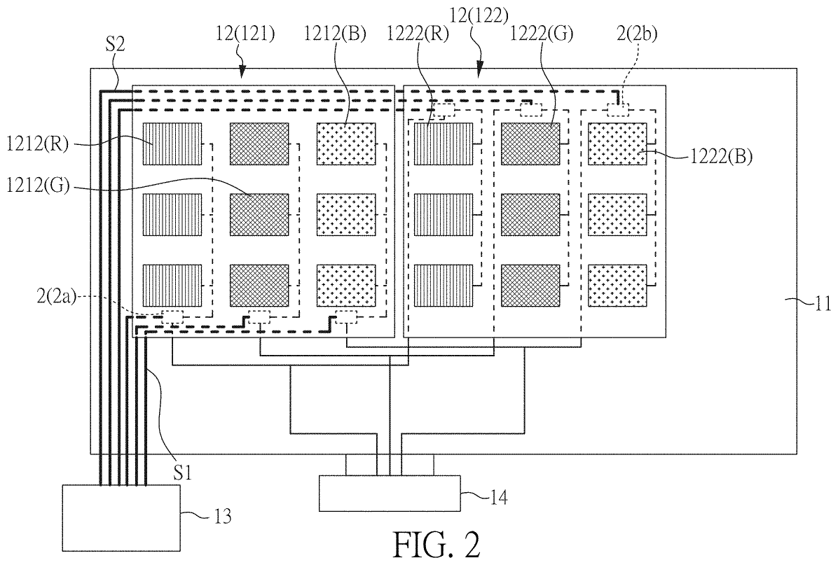

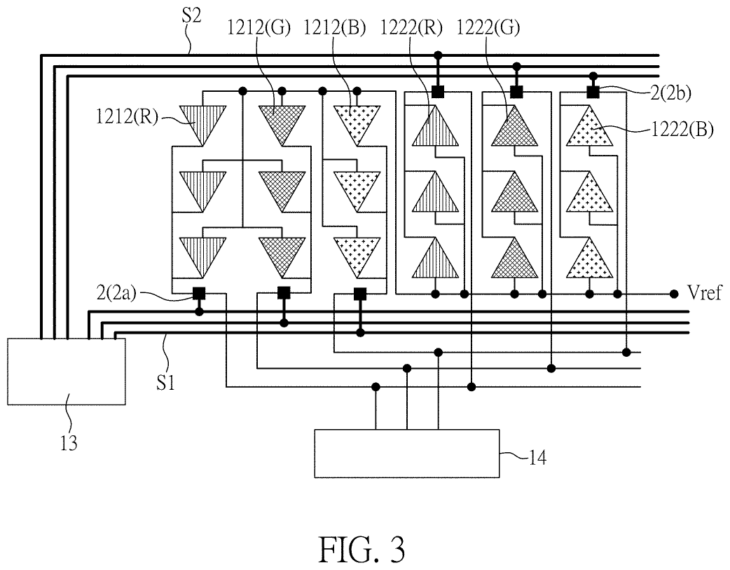

FIG. 2 is a schematic view showing a part of an electronic device of the present embodiment, and FIG. 3 is a circuit diagram of a part of an electronic device of the present embodiment. Herein, only two of the electronic modules are exemplified in FIG. 2 and FIG. 3 to clearly show the features of the electronic device of the present embodiment. The features of other electronic modules are similar to those of the two electronic modules shown in FIG. 2 and FIG. 3, and are not repeated again.

As shown in FIG. 2, the electronic device of the present embodiment further comprises: a first signal line Si disposed on the substrate 11; and a plurality of switch elements 2 disposed on the substrate 1 and comprising a first switch element 2a, wherein the first switch element 2a is electrically connected to the first signal line S1, and at least one of the first electronic elements 1212 is electrically connected to the first switch element 2a. In addition, the electronic device of the present embodiment further comprises: a second signal line S2 disposed on the substrate 11, wherein the switch elements 2 further comprise a second switch element 2b electrically connected to the second signal line S2, and at least one of the second electronic elements 1222 is electrically connected to the second switch element 2b.

Herein, the first signal line S1 and the second signal line S2 are extended beneath at least one of the plurality of electronic modules 12. In the present embodiment, the first signal line S1 is extended beneath the first electronic module 121, and the second signal line S2 is extended beneath the first electronic module 121 and the second electronic module 122. In addition, in FIG. 2, the first signal line S1 and the second signal line S2 are not extended beneath the electronic elements (for example, the first electronic elements 1212 and the second electronic elements 1222), but the first signal line S1 and the second signal line S2 can be extended beneath the electronic elements in other embodiments of the present disclosure.

In addition, the switch elements 2 (for example, the first switch element 2a and the second switch element 2b) are also disposed under at least one of the plurality of electronic modules 12. In the present embodiment, the first switch element 2a is disposed under the first electronic module 121, and the second switch element 2b is disposed under second electronic module 122. In addition, in FIG. 2, the first switch element 2a and the second switch element 2b are not disposed under the electronic elements (for example, the first electronic elements 1212 and the second electronic elements 1222), but the first switch element 2a and the second switch element 2b can be disposed under the electronic elements in other embodiments of the present disclosure.

The first electronic module 121 comprises the first electronic elements 1212 having red color (R), green color (G) and blue color (B), and the second electronic module 122 also comprises the second electronic elements 1222 having red color (R), green color (G) and blue color (B). However, the present disclosure is not limited thereto. In another embodiment of the present disclosure, the first electronic elements 1212 and the second electronic elements 1222 may have red color, green color, blue color and white color. In another embodiment of the present disclosure, the first electronic elements 1212 and the second electronic elements 1222 may have red color, green color, blue color and yellow color. In further another embodiment of the present disclosure, the first electronic elements 1212 and the second electronic elements 1222 may have red color, first green color, second green color, and blue color, and the first green color and the second green color have peak emission wavelengths slightly different from each other. In yet another embodiment of the present disclosure, the first electronic elements 1212 and the second electronic elements 1222 may have red color, green color, first blue color, and second blue color, and the first blue color and the second blue color have peak emission wavelengths slightly different from each other. In the present embodiment, the first electronic elements 1212 and the second electronic elements 1222 are LED chips capable of emitting different colors.

In addition, the arrangement of the first electronic elements 1212 and the second electronic elements 1222 are not limited to the pattern shown in FIG. 2, and can be adjusted according to the need.

In the present embodiment, the switch elements 2 (for example, the first switch element 2a and the second switch element 2b) are thin film transistors, which can be a-Si thin film transistors, low temperature polysilicon (LTPS) thin film transistors, oxide thin film transistors (for example, IGZO thin film transistors, AIZO thin film transistors, HIZO thin film transistors, ITZO thin film transistors, IGZTO thin film transistors or IGTO thin film transistors), or a combination thereof, but the present disclosure is not limited thereto.

As shown in FIG. 1 to FIG. 3, the controller 13 is electrically connected to the first signal lines S1 and the second signal lines S2, and further electrically connected to gate electrodes (not shown in the figure) of the first switch elements 2a and the second switch elements 2b. The controller 13 provides signals, which are transmitted to the first switch elements 2a via the first signal lines S1 and to the second switch elements 2b via the second signal lines S2. Herein, the signals provided by the controller 13 are transmitted to the gate electrodes (not shown in the figure) of the first switch elements 2a and the second switch elements 2b. The controller 13 is a T-con controller, and the on/off operation of the switch elements 2 (for example, the first switch elements 2a and the second switch elements 2b) are determined by the controller 13. The driving element 14 is electrically connected to the first switch elements 2a and the second switch elements 2b, and for example electrically connected to source electrodes (not shown in the figure) of the first switch elements 2a and the second switch elements 2b. The driving element 14 also provides signals, which are transmitted to the source electrodes (not shown in the figure) of the first switch elements 2a and the second switch elements 2b. The driving element 14 is for example a pulse width modulation IC, which provides a constant voltage to the first switch elements 2a and the second switch elements 2b. After the first switch elements 2a and the second switch elements 2b receive the signals provided by the controller 13 and the driving element 14, the first electronic elements 1212 and the second electronic elements 1222 are driven to emit light. In some embodiments, the first electronic elements 1212 and the second electronic element 1222 are driven to emit light through a current coining from the first switch element 2a and the second switch element 2b respectively.

As shown in FIG. 3, one signal provided by the driving element 14 can be transmitted to one of the first switch elements 2a, and then three of the first electronic elements 1212 are triggered by the one of the first switch elements 2a. Similarly, another signal provided by the driving element 14 can be transmitted to one of second switch elements 2b, and then three of the second electronic elements 1222 are driven by the one of the second switch elements 2b. Thus, the first electronic elements 1212 and the second electronic elements 1222 are not driven directly by the driving element 14, but are driven via the first switch elements 2a and the second switch elements 2b. In the present embodiment, the first electronic element 1212 has a cathode electrically connected to the first switch element 2a and an anode electrically connected to a reference voltage Vref, such as a grounding voltage.

It is known that the number of the elements capable of being driven by one driving element 14 is limited, so more driving elements 14 are used when the first electronic elements 1212 and the second electronic elements 1222 are driven directly by the driving elements 14. However, in the electronic device of the present embodiment, less driving elements 14 are used because the driving elements 14 provide signals to the first switch elements 2a and the second switch elements 2b, and then the first electronic elements 1212 and the second electronic elements 1222 are driven by the first switch elements 2a and the second switch elements 2b according to the signals provided by the controller 13. Thus, the cost of the electronic device of the present embodiment can be reduced because the number of the used driving elements 14 is reduced in the electronic device of the present embodiment.

In the present embodiment, the controller 13 and the driving element 14 are two individual elements. In another embodiment of the present disclosure, the controller 13 and the driving element 14 can be integrated into one element.

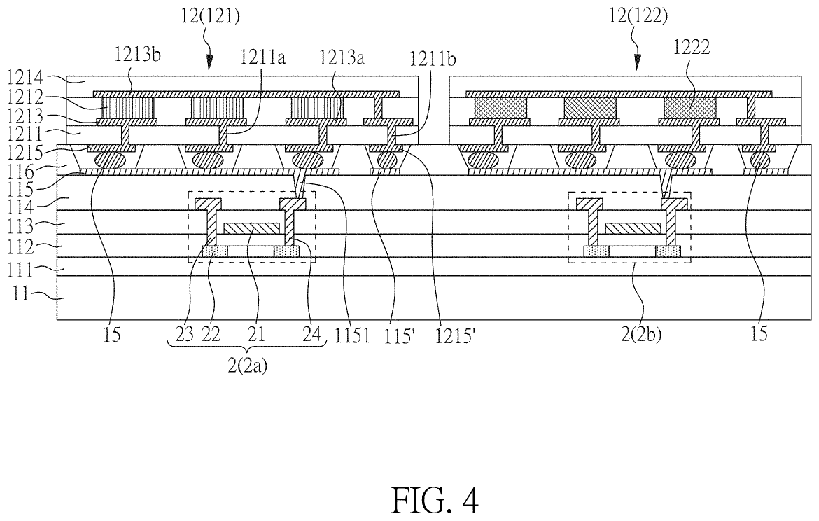

FIG. 4 is a cross-sectional view of an electronic device of the present embodiment. Herein, the switch elements 2 being an LTPS thin film transistor is exemplified, but the present disclosure is not limited thereto. In addition, the switch elements 2 is a top gate transistor in the present embodiment, and the switch elements 2 can be a bottom gate transistor in another embodiment of the present disclosure.

The electronic device of the present embodiment comprises: a substrate 11; a buffer layer 111 disposed on the substrate 11; a semiconductor layer 22 disposed on the buffer layer 111, wherein the semiconductor layer 22 is a polysilicon layer; a gate insulating layer 112 disposed on the semiconductor layer 22; a gate electrode 21 disposed on the gate insulating layer 112 and corresponding to the semiconductor layer 22; an insulating layer 113 disposed on the gate electrode 21; and a source electrode 23 and a drain electrode 24 disposed on the insulating layer 113 and electrically connected to the semiconductor layer 22. Herein, the gate electrode 21, the semiconductor layer 22, the source electrode 23 and the drain electrode 24 constitute the switch element 2 (i.e. the first switch element 2a). A planer layer 114 is disposed on the switch element 2. A first bonding pad 115 is disposed on the planer layer 114 and electrically connects to the switch element 2 via a contact via 1151, and a second bonding pad 115′ is also disposed on the planer layer 114. A separation layer 116 is disposed on the first bonding pad 115 and the second bonding pad 115′.

The buffer layer 111, the gate insulating layer 112, the insulating layer 113, the planer layer 114 and the separation layer 116 may respectively comprise, for example, silicon oxide, silicon oxynitride, silicon nitride, aluminum oxide, resin, polymer, photoresist, or a combination thereof. The gate electrode 21, the source electrode 23, the drain electrode 24 and the first bonding pad 115 can respectively have a single layer structure or a multi-layered structure. The gate electrode 21, the source electrode 23 and the drain electrode 24 may respectively comprise, for example, metal (such as Cu, Al, Ti, Cr or Mo), alloy thereof, metal oxide (such as ITO, IZO, ITZO, IGZO, or AZO), metal nitrogen oxide, or other electrode materials. The first bonding pad 115 or the second bonding pad 115′ may comprise, for example, metal (such as Cu, Ni, Au, Ag, Al, Ti, Cr, In, Sn or Mo), alloy thereof or metal oxide (such as ITO, IZO, ITZO, IGZO, or AZO).

The electronic device of the present embodiment further comprises: a plurality of electronic modules 12. Herein, only the first electronic module 121 of the electronic modules 12 is illustrated below, and the structures of the other electronic modules 12 are similar to the structure of the first electronic module 121 and are not repeated again.

As shown in FIG. 4, the first electronic module 121 comprises: a first substrate 1211; first electronic elements 1212 disposed on the first substrate 1211; a first circuit layer 1213 disposed between the first substrate 1211 and the first electronic elements 1212 and electrically connected to the first electronic elements 1212; and a first protective layer 1214 disposed on the first electronic elements 1212. Herein, the first circuit layer 1213 comprises a plurality of first electrodes 1213a, and each of the first electrodes 1213a is electrically connected to one of the first electronic elements 1212. The first electronic module 121 further comprises a second electrode 1213b electrically connected to the first electronic elements 1212. In the present embodiment, the second electrode 1213b is a common electrode. In addition, a plurality of first contact pads 1215 are disposed on a side of the first substrate 1211 facing to the substrate 11, and respectively electrically connected to the first electrodes 1213a via first through holes 1211a penetrating through the first substrate 1211. Thus, each of the first electronic elements 1212 is respectively electrically connected to one of the first contact pads 1215. Furthermore, a second contact pad 1215′ is also disposed on a side of the first substrate 1211 facing to the substrate 11, and electrically connected to the second electrode 1213b via a second through holes 1211b penetrating through the first substrate 1211. Herein, the first protective layer 1214 can be an encapsulating layer (for example, an inorganic-organic-inorganic layer), a polarizer or a substrate. The first contact pads 1215 or the second contact pad 1215′ may comprise, for example, metal (such as Cu, Ni, Au, Ag, Al, Ti, Cr, In, Sn or Mo), alloy thereof or metal oxide (such as ITO, IZO, ITZO, IGZO, or AZO).

In the present embodiment, each of the first contact pads 1215 is electrically connected to the first bonding pad 115 through a conductive element 15. In addition, the second contact pad 1215′ is electrically connected to the second bonding pad 115′ through another conductive element 15. Thus, the first electronic elements 1212 can be electrically connected to the first switch element 2a (for example the drain electrode 24 of the first switch element 2a) via the first bonding pad 115, the conductive element 15, the first contact pads 1215, the first through hole 1211a, and the first electrode 1213a. The second electronic elements 1222 can be electrically connected to the second switch element 2b in a similar manner described above.

### Embodiment 2

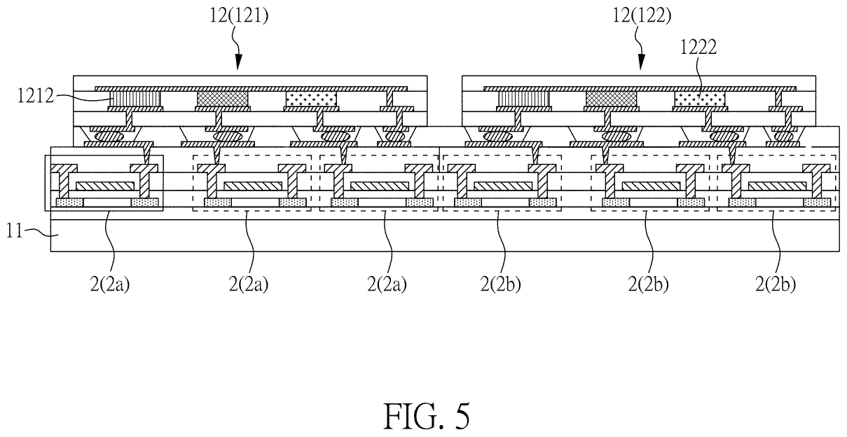

FIG. 5 is a cross-sectional view of an electronic device of the present embodiment. The electronic device of the present embodiment is similar to the electronic device of Embodiment 1, except for the following differences.

In the present embodiment, one first electronic element 1212 is driven by one first switch element 2a, and one second electronic element 1222 is driven by one second switch element 2b.

### Embodiment 3

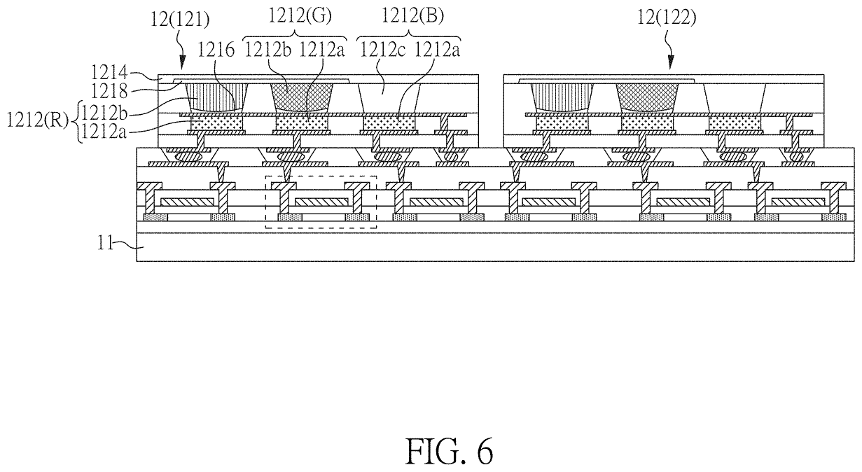

FIG. 6 is a cross-sectional view of an electronic device of the present embodiment. The electronic device of the present embodiment is similar to the electronic device of Embodiment 2, except for the following differences.

In Embodiment 2, the first electronic elements 1212 comprises LED chips capable of emitting different colors. In the present embodiment, the first electronic element 1212 emitting red color (R) comprises: an LED chip 1212a capable of emitting blue color; and a light conversion element 1212b disposed on the LED chip 1212a to convert the blue light emitting from the LED chip 1212a into red light. The light conversion element 1212b may comprise quantum-dot, phosphors, or photoresist. Similarly, the first electronic element 1212 emitting green color (G) comprises: a LED chip 1212a capable of emitting blue color; and a light conversion element 1212b disposed on the LED chip 1212a to convert the blue light emitting from the LED chip 1212a into green light. The first electronic element 1212 emitting blue color (B) comprises: a LED chip 1212a capable of emitting blue color; and a light scattering element 1212c containing scattering particles and disposed on the LED chip 1212a. In addition, a buffer layer 1216 is further disposed between the LED chip 1212a and the light conversion element 1212b. The buffer layer 1216 blocks the light conversion element 1212b from directly contacting the LED chip 1212a because the heat generated by the LED chip 1212a may damage the light conversion element 1212b. The buffer layer 1216 may comprise epoxy or silicone. In addition, a light alternating layer 1218 is further disposed on the light conversion elements 1212b of the first electronic elements 1212 emitting red color (R) and green color (G) to filter out the residual blue color which are not converted by the light conversion elements 1212b. In some embodiments, the light scattering element 1212c can be replaced by a polymer layer without containing scattering particles.

### Embodiment 4

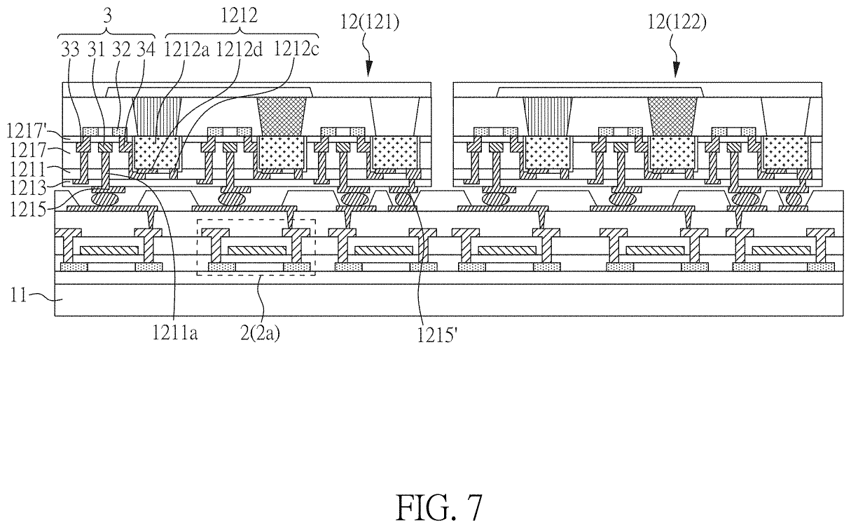

FIG. 7 is a cross-sectional view of an electronic device of the present embodiment. The electronic device of the present embodiment is similar to the electronic device of Embodiment 3, except for the following differences.

In the present embodiment, the first electronic module 121 further comprises a plurality of first transistors 3, each of first transistors 3 is electrically connected to one of the first switch element 2a and one of the first electronic elements 1212 respectively.

More specifically, the first electronic module 121 comprises: the first substrate 1211; the first circuit layer 1213 disposed under the first substrate 1211; a first insulating layer 1217 disposed on the first substrate 1211; a first gate insulating layer 1217′ disposed on the first insulating layer 1217; a first gate electrode 31, a first source electrode 33 and a first drain electrode 34 disposed between the first insulating layer 1217 and the first gate insulating layer 1217′; and a semiconductor layer 32 disposed on the first gate insulating layer 1217′. Herein, the first gate electrode 31, the semiconductor layer 32, the first source electrode 33 and the first drain electrode 34 constitute the first transistor 3. The first gate electrode 31 is electrically connected to the first contact pad 1215 via a first through hole 1211a penetrating through the first substrate 1211. The first source electrode 33 is electrically connected to the first circuit layer 1213. The first drain electrode 34 is electrically connected to a first electrode 1212d of the first electronic element 1212. A second electrode 1212c of the first electronic element 1212 is electrically connected to a second contact pad 1215′ disposed on a side of the first substrate 1211 facing to the substrate 11.

The structure of the second electronic module 122 is similar to the structure of the first electronic module 121, and is not repeated again.

### Embodiment 5

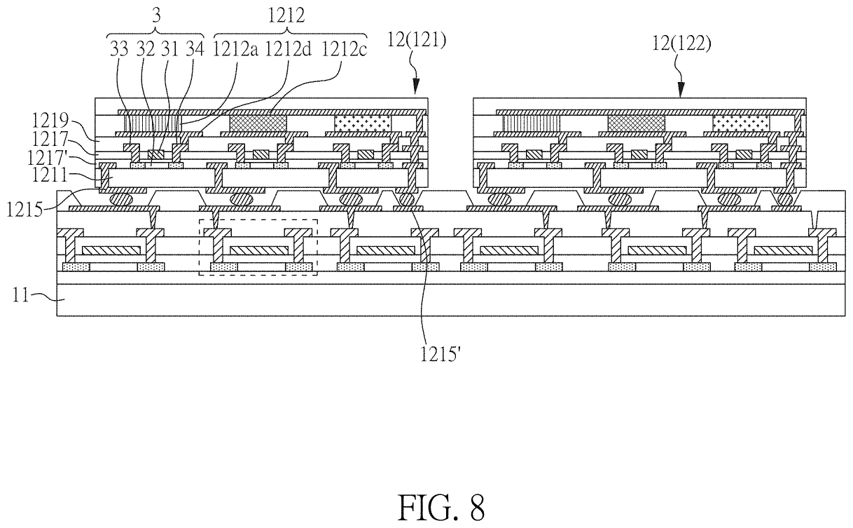

FIG. 8 is a cross-sectional view of an electronic device of the present embodiment. The electronic device of the present embodiment is similar to the electronic device of Embodiment 4, except for the following differences.

In the present embodiment, the first transistor is a top gate transistor. More specifically, the first electronic module 121 comprises: the first substrate 1211; a semiconductor layer 32 disposed on the first substrate 1211; a first gate insulating layer 1217′ disposed on the semiconductor layer 32; a first gate electrode 31 disposed on the first gate insulating layer 1217′; a first insulating layer 1217 disposed on the first gate insulating layer 1217′; a first source electrode 33 and a first drain electrode 34 disposed on the first insulating layer 1217 and electrically connected to the semiconductor layer 32; and a second insulating layer 1219 disposed on the first source electrode 33 and the first drain electrode 34. Herein, the first gate electrode 31, the semiconductor layer 32, the first source electrode 33 and the first drain electrode 34 constitute the first transistor 3. Even though not shown in the figure, in another cross-sectional view of the electronic device of the present embodiment, the first gate electrode 31 is electrically connected to the first contact pad 1215. In addition, the first drain electrode 34 is electrically connected to a first electrode 1212d of the first electronic element 1212. A second electrode 1212c of the first electronic element 1212 is electrically connected to a second contact pad 1215′ disposed on a side of the first substrate 1211 facing to the substrate 11. In the present embodiment, the first electronic element 1212 is similar to that shown in FIG. 4, and are not repeated again.

The structure of the second electronic module 122 is similar to the structure of the first electronic module 121, and is not repeated again.

The first gate insulating layer 1217′, the first insulating layer 1217 and the second insulating layer 1219 mentioned in Embodiments 4 and 5 may comprise, for example, silicon oxide, silicon oxynitride, silicon nitride, aluminum oxide, resin, polymer, photoresist, or a combination thereof. In addition, the materials for the first transistor 3 can be similar to those for the switch element 2 (for example, the first switch element 2a) mentioned in Embodiment 1, and are not repeated again.

The display panel and the display device made as described in any of the embodiments of the present disclosure as described previously can be co-used with a touch panel to form a touch display device. The tiled display device of the present disclosure can be applied to any electronic devices that need a display screen, such as displays, mobile phones, laptops, video cameras, still cameras, music players, mobile navigators, TV sets, and other electronic devices that display images. The tiled display system of the present disclosure can be applied to any electronic devices that need to display large images, such as video walls, and advertising boards.

Although the present disclosure has been explained in relation to its embodiment, it is to be understood that many other possible modifications and variations can be made without departing from the spirit and scope of the disclosure as hereinafter claimed.

What is claimed is:

1. An electronic device, comprising
a substrate;
a first signal line disposed on the substrate;
a plurality of switch elements disposed on the substrate and comprising a first switch element, wherein the first switch element is electrically connected to the first signal line;
a plurality of electronic modules disposed on the substrate and comprising a first electronic module, wherein the first electronic module comprises a first substrate, a plurality of first electronic elements disposed on the first substrate, a plurality of first electrodes, a second electrode and a plurality of first contact pads disposed on the substrate, wherein the plurality of first electrodes are disposed between the first substrate and the second electrode, the first substrate is disposed between the plurality of first electrodes and the plurality of first contact pads, and the second electrode is electrically connected to the plurality of first electronic elements; and
a light alternating layer disposed on the substrate;
wherein at least two of the plurality of first electronic elements respectively comprise an LED chip, and a light conversion element disposed on the LED chip, and the light alternating layer is continuously disposed on two adjacent light conversion elements of the at least two of the plurality of first electronic elements.

2. The electronic device of claim 1, wherein each of the plurality of switch elements is a thin film transistor.

3. The electronic device of claim 1, wherein the first electronic module is electrically connected to the first signal line through a conductive element.

4. The electronic device of claim 1, wherein the first signal line is extended beneath at least one of the plurality of electronic modules.

5. The electronic device of claim 1, wherein the plurality of switch elements are disposed beneath at least one of the plurality of electronic modules.

6. The electronic device of claim 1, further comprising a controller electrically connected to the first signal line.

7. The electronic device of claim 6, further comprising a driving element electrically connected to the first switch element.

8. The electronic device of claim 7, wherein the driving element is electrically connected to a source electrode of the first switch element, the controller is electrically connected to a gate electrode of the first switch element, and at least one of the plurality of first electronic elements is electrically connected to a drain electrode of the first switch element.

9. The electronic device of claim 1, wherein a planer layer is disposed on the plurality of switch elements, a plurality of first bonding pads are disposed on the planer layer and respectively electrically connected to the plurality of switch elements, and at least one of the plurality of first electronic elements is electrically connected to the first switch element via one of the plurality of first bonding pads.

10. The electronic device of claim 9, wherein the plurality of first contact pads are disposed on a side of the first substrate facing to the substrate, and each of the plurality of first electronic elements is electrically connected to one of the plurality of first contact pads respectively.

11. The electronic device of claim 10, wherein one of the plurality of first contact pads is electrically connected to one of the plurality of first bonding pads through a conductive element.

12. The electronic device of claim 1, wherein at least one of the at least two of the plurality of first electronic elements further comprises a buffer layer disposed between the LED chip and the light conversion element.

13. The electronic device of claim 1, wherein the first electronic module further comprises a plurality of first transistors, each of the plurality of first transistors is electrically connected to the first switch element and at least one of the plurality of first electronic element respectively.

14. The electronic device of claim 1, wherein the plurality of electronic modules are arranged in juxtaposition.

15. The electronic device of claim 1, wherein each of the plurality of first electronic elements is a light emitting diode, an antenna unit, a sensor, or a combination thereof.

16. The electronic device of claim 1, wherein at least one of the plurality of first electronic elements is electrically connected to the first switch element via at least one of the plurality of first contact pads and at least one of a plurality of first through holes penetrating through the first substrate.

17. A method for manufacturing an electronic device, comprising:
providing a substrate;
forming a first signal line on the substrate;
forming a plurality of switch elements on the substrate, wherein the plurality of switch elements comprises a first switch element;
disposing a plurality of electronic modules on the substrate, wherein the plurality of electronic modules comprises a first electronic module, and the first electronic module comprises a first substrate, a plurality of first electronic elements disposed on the first substrate, a plurality of first electrodes, a second electrode and a plurality of first contact pads disposed on the substrate, wherein the plurality of first electrodes are disposed between the first substrate and the second electrode, the first substrate is disposed between the plurality of first electrodes and the plurality of first contact pads, and the second electrode is electrically connected to the plurality of first electronic elements; and
disposing a light alternating layer on the substrate;
wherein at least two of the plurality of first electronic elements respectively comprise an LED chip, and a light conversion element disposed on the LED chip, and the light alternating layer is continuously disposed on two adjacent light conversion elements of the at least two of the plurality of first electronic elements.
